(19) United States
(12) Patent Application Publication
(10) Pub. No.: US 2025/0294830 A1
(43) Pub. Date: Sep. 18, 2025

(54) SEMICONDUCTOR DEVICE

(71) Applicants: KABUSHIKI KAISHA TOSHIBA, Tokyo (JP); TOSHIBA ELECTRONIC DEVICES & STORAGE CORPORATION, Tokyo (JP)

(72) Inventors: Yusuke KOBAYASHI, Yokohama (JP); Tatsunori SAKANO, Tokyo (JP); Tomoaki INOKUCHI, Yokohama (JP); Shotaro BABA, Kawasaki (JP); Tatsuo SHIMIZU, Tokyo (JP); Ryohei GEJO, Kawasaki (JP); Tomoko MATSUDAI, Tokyo (JP)

(73) Assignees: KABUSHIKI KAISHA TOSHIBA, Tokyo (JP); TOSHIBA ELECTRONIC DEVICES & STORAGE CORPORATION, Tokyo (JP)

(21) Appl. No.: 19/033,614

(22) Filed: Jan. 22, 2025

(30) Foreign Application Priority Data
Mar. 13, 2024 (JP) 2024-039159

(51) Int. Cl. H10D 62/10; H10D 12/00

(52) U.S. Cl. CPC H10D 62/124; H10D 12/481

(57) ABSTRACT

A semiconductor device includes first and second electrodes, a semiconductor layer, first and second gate electrodes, and first and second insulating regions. The first gate electrode is provided on a side of the semiconductor layer facing the first electrode. The second gate electrode is provided on a side of the semiconductor layer facing the second electrode. The semiconductor layer includes first to sixth semiconductor regions. The second semiconductor region is provided between the first semiconductor region and the first electrode. The third semiconductor region is electrically connected to the first electrode. The fourth semiconductor region is provided between the first semiconductor region and the second electrode. The fifth semiconductor region is separated from the fourth semiconductor region. The sixth semiconductor region includes a first region. The first region is provided between the fourth semiconductor region and the fifth semiconductor region, and is opposed to the second gate electrode.

### CROSS-REFERENCE TO RELATED APPLICATIONS

This application is based upon and claims the benefit of priority from Japanese Patent Application No. 2024-039159, filed on Mar. 13, 2024; the entire contents of which are incorporated herein by reference.

### FIELD

Embodiments described herein relate to a semiconductor device.

### BACKGROUND

For example, there are semiconductor devices such as IGBTs (Insulated Gate Bipolar Transistors).

### BRIEF DESCRIPTION OF THE DRAWINGS

FIG. 1 is a schematic cross-sectional view of a semiconductor device according to an embodiment;

FIG. 2 is a schematic cross-sectional view of the semiconductor device according to the embodiment;

FIGS. 3A and 3B are schematic diagrams illustrating an operation of the semiconductor device according to the embodiment;

FIG. 4 is a schematic cross-sectional view of a semiconductor device according to a reference example;

FIG. 5 is a schematic cross-sectional view of a semiconductor device according to the embodiment;

FIG. 6 is a schematic cross-sectional view of the semiconductor device according to the embodiment;

FIG. 7 is a schematic cross-sectional view of a semiconductor device according to the embodiment;

FIG. 8 is a schematic cross-sectional view of a semiconductor device according to the embodiment;

FIG. 9 is a schematic cross-sectional view of a semiconductor device according to the embodiment; and

FIG. 10 is a schematic cross-sectional view of a semiconductor device according to the embodiment.

### DETAILED DESCRIPTION

According to an embodiment, a semiconductor device includes a first electrode, a second electrode, a semiconductor layer, a first gate electrode, a second gate electrode, a first insulating region, and a second insulating region. A direction from the second electrode toward the first electrode is along a first direction. The semiconductor layer is provided between the first electrode and the second electrode. The semiconductor layer has a first surface facing the first electrode and a second surface opposite to the first surface. The first surface and the second surface extend along a second direction perpendicular to the first direction. The first gate electrode is provided on a side of the semiconductor layer facing the first electrode. The second gate electrode is provided on a side of the semiconductor layer facing the second electrode. The second surface is located between the first surface and the second electrode. The first insulating region is provided between the first gate electrode and the semiconductor layer. The second insulating region is provided between the second gate electrode and the second surface of the semiconductor layer. The semiconductor layer includes a first semiconductor region of a first conductivity type, a second semiconductor region of the first conductivity type, a third semiconductor region of a second conductivity type, a fourth semiconductor region of the second conductivity type, a fifth semiconductor region of the second conductivity type, and a sixth semiconductor region of the first conductivity type. The second semiconductor region is provided between the first semiconductor region and the first electrode and is electrically connected to the first electrode. The third semiconductor region is electrically connected to the first electrode. A part of the third semiconductor region is provided between the first semiconductor region and the second semiconductor region, is in contact with the first insulating region, and is opposed to the first gate electrode. The fourth semiconductor region is provided between the first semiconductor region and the second electrode and is electrically connected to the second electrode. The fifth semiconductor region is separated from the fourth semiconductor region in the second direction. The sixth semiconductor region includes a first region. The first region is provided between the fourth semiconductor region and the fifth semiconductor region, is in contact with the second insulating region, and is opposed to the second gate electrode.

Hereinafter, embodiments of the invention will be described with reference to the drawings.

The drawings are schematic or conceptual, and the relationship between the thickness and width of each portion, the proportions of sizes among portions, and so on are not necessarily the same as the actual values. Even the dimensions and proportion of the same portion may be illustrated differently depending on the drawing.

In the specification and drawings, components similar to those described in regard to a drawing thereinabove are marked with like reference numerals, and a detailed description is omitted as appropriate.

In the following descriptions and drawings, notations of n⁺, n, n⁻ and p⁺, p, p⁻ represent relative levels of impurity concentrations. That is, a notation with “+” indicates that the impurity concentration is relatively higher than a notation without any of “+” or “−”, and a notation with “−” indicates that the impurity concentration is relatively lower than a notation without any of “+” or “−”. These notations represent, when both a p-type impurity and an n-type impurity are contained in each of the regions, relative levels of net impurity concentrations after these impurities compensate each other. Each of the embodiments described below may be implemented by inverting the p-type (second conductivity type) and the n-type (first conductivity type) of each of the semiconductor regions.

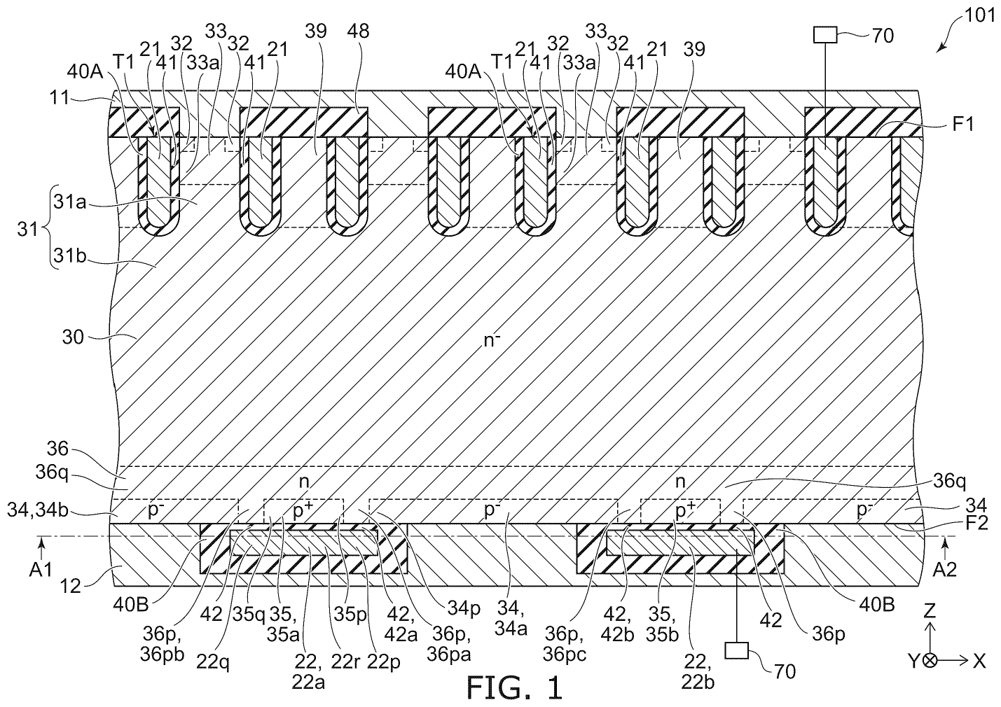

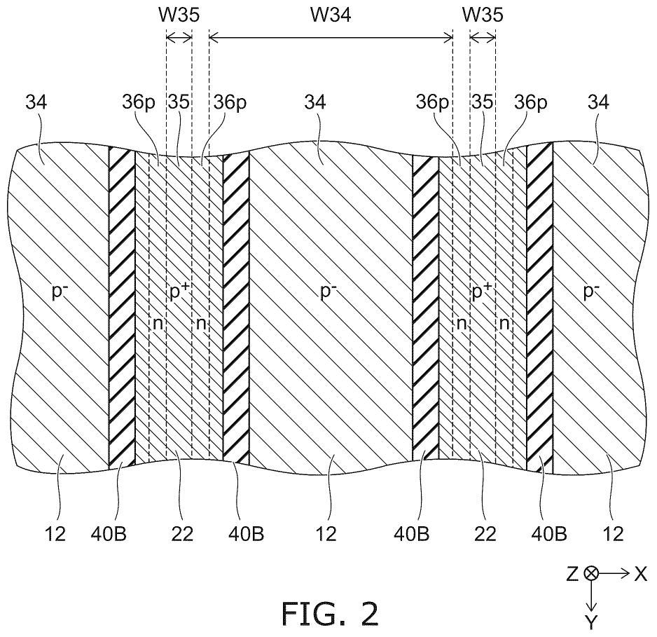

FIG. 1 and FIG. 2 are schematic cross-sectional views of a semiconductor device according to an embodiment.

FIG. 2 illustrates a cross section taken along line A1-A2 in FIG. 1. In FIG. 2, the positions of semiconductor regions on the back surface side of a semiconductor layer 30 are indicated by dashed lines. Further, the impurity concentrations (for example, n, p⁺, and p⁻) of these semiconductor regions are indicated.

As shown in FIG. 1, a semiconductor device 101 according to the embodiment includes a first electrode 11 (for example, an emitter electrode), a second electrode 12 (for example, a collector electrode), and the semiconductor layer 30. The semiconductor layer 30 is provided between the first electrode 11 and the second electrode 12.

The direction from the second electrode 12 toward the first electrode 11 is along a first direction. In the description of the embodiment, the first direction is defined as a Z-direction. A direction intersecting the first direction is defined as a second direction (X-direction). The X-direction needs to be a direction perpendicular to the Z-direction. A direction intersecting the first direction and the second direction is defined as a third direction (Y-direction). The Y-direction needs to be a direction perpendicular to the Z-direction and the X-direction.

The semiconductor layer 30 has a first surface F1 (for example, a front surface) and a second surface F2 (for example, a back surface). The first surface F1 is a surface of the semiconductor layer 30 facing the first electrode 11. The second surface F2 is a surface of the semiconductor layer 30 facing the second electrode 12, and is opposite to the first surface F1 of the semiconductor layer 30. The first surface F1 and the second surface F2 each extend along an X-Y plane perpendicular to the Z-direction.

In the description of the embodiments, for convenience, a side of the semiconductor layer 30 facing the first electrode 11 may be referred to as “front” (front side) or “upper”, and a side of the semiconductor layer 30 facing the second electrode 12 may be referred to as “back” (back side) or “lower”. The terms “front”, “back”, “upper”, and “lower” are based on the relative positional relationship between the first electrode 11 and the second electrode 12, and do not limit the direction of gravity or the manufacturing process.

The semiconductor device 101 includes a plurality of first gate electrodes 21 (front gate electrodes) and a plurality of first insulating regions 41 (front gate insulating films) provided on the front side of the semiconductor layer 30. The first insulating region 41 is a part of a first insulating portion 40A, which insulates the semiconductor layer 30 and the first gate electrode 21 from each other.

The plurality of first gate electrodes 21 are arranged side by side in the X-direction. Each first gate electrode 21 extends in the Y-direction. The first gate electrode 21 extends from the first surface F1 toward the second surface F2. The plurality of first insulating regions (the first insulating portions 40A) are respectively provided between the plurality of first gate electrodes 21 and the semiconductor layer 30.

That is, in this example, the first gate electrode 21 is a trench gate. A trench T1 extending toward the second surface F2 is provided in the first surface F1 of the semiconductor layer 30. The first insulating portion 40A is provided inside the trench T1. The first gate electrode 21 is provided inside the first insulating portion 40A. The first gate electrode 21 is insulated from the semiconductor layer 30.

The semiconductor layer 30 includes a first semiconductor region 31 (drift region) of the first conductivity type. In this example, the first conductivity type is the n-type. A lower portion 31b of the first semiconductor region 31 is located below the first gate electrode 21 and is in contact with the first insulating portion 40A. That is, the direction from the lower portion 31b toward the first gate electrode 21 is along the Z-direction. An upper portion 31a of the first semiconductor region 31 is opposed to the first gate electrode 21 with the first insulating region 41 interposed therebetween. The direction from the upper portion 31a toward the first gate electrode 21 is along the X-direction. The upper portion 31a is in contact with the first insulating region 41. The first insulating region 41 is between the upper portion 31a and the first gate electrode 21.

The semiconductor layer 30 further includes a plurality of second semiconductor regions 32 (emitter regions), a plurality of third semiconductor regions 33 (base regions), and a plurality of semiconductor regions 39 provided on the front side. The second semiconductor region 32, the third semiconductor region 33, and the semiconductor region 39 are adjacent to the first insulating portion 40A, and extend in the Y-direction along the first insulating portion 40A (the first gate electrode 21).

The second semiconductor region 32 is of the first conductivity type. The second semiconductor region 32 is provided between the first semiconductor region 31 and the first electrode 11. The second semiconductor region 32 is in contact with the first electrode 11 and is electrically connected to the first electrode 11. The second semiconductor region 32 is opposed to the first gate electrode 21 with the first insulating region 41 interposed therebetween. The direction from the second semiconductor region 32 toward the first gate electrode 21 is along the X-direction. The second semiconductor region 32 is in contact with the first insulating region 41. The first insulating region 41 is between the second semiconductor region 32 and the first gate electrode 21. The second semiconductor region 32 is provided on top of a part of the third semiconductor region 33 and is separated from the first semiconductor region 31. The direction from the first semiconductor region 31 (the upper portion 31a) toward the second semiconductor region 32 is along the Z-direction.

The third semiconductor region 33 is of the second conductivity type. In this example, the second conductivity type is the p-type. The third semiconductor region 33 is in contact with the first electrode 11 and is electrically connected to the first electrode 11. The third semiconductor region 33 is provided on top of the upper portion 31a of the first semiconductor region 31. A part 33a of the third semiconductor region 33 is located between the first semiconductor region 31 (the upper portion 31a) and the second semiconductor region 32. The third semiconductor region 33 is in contact with the first semiconductor region 31 and the second semiconductor region 32 (forms a p-n junction). The part 33a of the third semiconductor region 33 is opposed to the first gate electrode 21 with the first insulating region 41 interposed therebetween. The direction from the part 33a toward the first gate electrode 21 is along the X-direction. The part 33a is in contact with the first insulating region 41. The first insulating region 41 is between the part 33a and the first gate electrode 21.

The semiconductor region 39 is of the second conductivity type and is provided on top of the first semiconductor region 31. One first gate electrode 21 is disposed between one semiconductor region 39 and one third semiconductor region 33. One third semiconductor region 33 is disposed between two adjacent first gate electrodes 21 among the plurality of first gate electrodes 21. Two second semiconductor regions 32 are disposed on top of one third semiconductor region 33.

An insulating portion 48 is provided between the first electrode 11 and the first gate electrode 21, between the first electrode 11 and the first insulating portion 40A, and between the first electrode 11 and the semiconductor region 39. The first electrode 11 and the first gate electrode 21 are insulated from each other.

The semiconductor device 101 further includes a plurality of second gate electrodes 22 (back gate electrodes) and a plurality of second insulating regions 42 (back gate insulating films) provided on the back side of the semiconductor layer 30. The second insulating region 42 is a part of a second insulating portion 40B, which covers the second gate electrode 22. The second insulating portion 40B (the second insulating region 42) is provided between the semiconductor layer 30 and the second gate electrode 22, and insulates the semiconductor layer 30 and the second gate electrode 22 from each other. The second insulating portion 40B is provided between the second electrode 12 and the second gate electrode 22, and insulates the second electrode 12 and the second gate electrode 22 from each other.

The second surface F2 is located between the first surface F1 and the second gate electrode 22. The second insulating region 42 is located between the second surface F2 and the second gate electrode 22. The plurality of second gate electrodes 22 are arranged side by side in the X-direction. Each second gate electrode 22 extends in the Y-direction.

The semiconductor layer 30 further includes a plurality of fourth semiconductor regions 34 (collector regions), a plurality of fifth semiconductor regions 35 (back side regions), and a sixth semiconductor region 36 provided on the back side. The sixth semiconductor region 36 includes a plurality of first regions 36p (channel regions) and a second region 36q (a buffer region). The fourth semiconductor region 34, the fifth semiconductor region 35, and the sixth semiconductor region 36 (the first region 36p) extend in the Y-direction along the second insulating portion 40B (the second gate electrode 22).

The fourth semiconductor region 34 is of the second conductivity type. The fourth semiconductor region 34 is provided between the first semiconductor region 31 and the second electrode 12. The fourth semiconductor region 34 is in contact with the second electrode 12 and is electrically connected to the second electrode 12.

An end portion 34p of the fourth semiconductor region 34 in the X-direction is in contact with the second insulating region 42. The end portion 34p of the fourth semiconductor region 34 may overlap the second gate electrode 22 and the second insulating region 42 in the Z-direction. In other words, the direction from a part of the second gate electrode 22 toward the end portion 34p of the fourth semiconductor region 34 is along the Z-direction. A part of the second insulating region 42 is between the part of the second gate electrode 22 and the end portion 34p of the fourth semiconductor region 34.

The fifth semiconductor region 35 is of the second conductivity type. The fifth semiconductor region 35 is separated from the fourth semiconductor region 34 in the X-direction. That is, the direction from the fifth semiconductor region 35 toward the fourth semiconductor region 34 is along the X-direction. The fifth semiconductor region 35 is located between the first semiconductor region 31 and the second insulating portion 40B (the second insulating region 42) in the Z-direction. The fifth semiconductor region 35 is separated from the second electrode 12.

The fifth semiconductor region 35 is in contact with the second insulating portion 40B (the second insulating region 42). An end portion 35p of the fifth semiconductor region 35 in the X-direction may overlap the second gate electrode 22 and the second insulating region 42 in the Z-direction. In other words, the direction from a part of the second gate electrode 22 toward the end portion 35p of the fifth semiconductor region 35 is along the Z-direction. A part of the second insulating region 42 is between the part of the second gate electrode 22 and the end portion 35p of the fifth semiconductor region 35. The entire lower surface (a surface facing the second electrode 12) of the fifth semiconductor region 35 is in contact with the second insulating portion 40B. For example, both end portions (the end portion 35p and an end portion 35q) of the fifth semiconductor region 35 in the X-direction are in contact with the second insulating portion 40B and overlap the second gate electrode 22 in the Z-direction.

The sixth semiconductor region 36 (the first region 36p and the second region 36q) is of the first conductivity type. The concentration of the first-conductivity-type impurity in the sixth semiconductor region 36 is higher than the concentration of the first-conductivity-type impurity in the first semiconductor region 31. The concentration of the first-conductivity-type impurity in the sixth semiconductor region 36 is, for example, 1×10¹⁶ atoms/cm³ or more and 1×10¹⁸ atoms/cm³ or less. The concentration of the first-conductivity-type impurity in the sixth semiconductor region 36 is, for example, 10³ times or more and 10⁵ times or less the concentration of the first-conductivity-type impurity in the first semiconductor region 31.

The first region 36p is provided between the fourth semiconductor region 34 and the fifth semiconductor region 35. The first region 36p is in contact with the fourth semiconductor region 34 (forms a p-n junction), and is in contact with the fifth semiconductor region 35 (forms a p-n junction). The first region 36p is in contact with the second insulating region 42. The first region 36p is opposed to the second gate electrode 22 with the second insulating region 42 interposed therebetween. The first region 36p overlaps the second gate electrode 22 and the second insulating region 42 in the Z-direction. In other words, the direction from the second gate electrode 22 toward the first region 36p is along the Z-direction. The second insulating region 42 is between the sixth semiconductor region 36 and the second gate electrode 22. The fifth semiconductor region 35 is located between two first regions 36p adjacent to each other in the X-direction and opposed to the same second gate electrode 22 in the Z-direction. The fifth semiconductor region 35 is located between two first regions 36p that are in contact with the same second insulating region 42.

The second region 36q is provided on top of the first region 36p, on top of the fourth semiconductor region 34, and on top of the fifth semiconductor region 35. That is, the second region 36q is provided between the first region 36p and the first semiconductor region 31, between the fourth semiconductor region 34 and the first semiconductor region 31, and between the fifth semiconductor region 35 and the first semiconductor region 31. The second region 36q is in contact with the fourth semiconductor region 34 (forms a p-n junction), and is in contact with the fifth semiconductor region 35 (forms a p-n junction). The fourth semiconductor region 34 and the fifth semiconductor region 35 need to be surrounded by the sixth semiconductor region 36 and separated from the first semiconductor region 31.

An example of the material of each component of the semiconductor device 101 will be described.

Each of the semiconductor regions (for example, the first to sixth semiconductor regions) of the semiconductor layer 30 contains silicon, silicon carbide, gallium nitride, or gallium arsenide as a semiconductor material. The semiconductor layer 30 is, for example, a silicon substrate. When silicon is used as the semiconductor material, arsenic, phosphorus, or antimony can be used as the n-type impurity. Boron can be used as the p-type impurity.

The first gate electrode 21 and the second gate electrode 22 contain, for example, a conductive material, such as polysilicon.

The first insulating portion 40A (for example, the first insulating region 41), the second insulating portion 40B (for example, the second insulating region 42), and the insulating portion 48 contain an insulating material, such as silicon oxide.

The first electrode 11 and the second electrode 12 contain metal, such as aluminum.

The semiconductor device 101 according to the embodiment operates as, for example, an IGBT (Insulated Gate Bipolar Transistor). For example, the first gate electrode 21 is in an ON state in a state in which a positive voltage is applied to the second electrode 12 relative to the first electrode 11. That is, this is a state in which, for example, a voltage higher than or equal to a threshold value (ON voltage) is applied to the first gate electrode 21, and the potential of the first gate electrode 21 is higher than or equal to a first threshold. Accordingly, an inversion layer is formed in the third semiconductor region 33 (base region). For example, electrons are injected from the first electrode 11 into the first semiconductor region 31 (drift region) through the second semiconductor region 32 (source region) and a channel. For example, holes are injected from the second electrode 12 into the first semiconductor region 31 via the fourth semiconductor region 34 (collector region). Thereafter, the first gate electrode 21 is in an OFF state. That is, this is a state in which, for example, the voltage applied to the first gate electrode 21 becomes lower than the threshold value, and the potential of the first gate electrode 21 is lower than the first threshold value. Accordingly, the inversion layer in the first semiconductor region 31 disappears.

The second gate electrode 22, the fourth semiconductor region 34, the fifth semiconductor region 35, and the first region 36p provided on the back surface side of the semiconductor layer 30 operate as, for example, a MOSFET (metal-oxide-semiconductor field-effect transistor). In this example, a p-channel MOSFET is formed. When the MOSFET is turned on and off, the injection efficiency of carriers from the back surface side of the semiconductor layer 30 can be controlled. When the carrier concentration in the semiconductor layer 30 is controlled, the ON voltage of the semiconductor device 101 can be reduced. Further, the turn-off loss of the semiconductor device 101 can be reduced.

For example, the second gate electrode 22 is in the ON state in a state in which a positive voltage is applied to the second electrode 12 relative to the first electrode 11. That is, this is a state in which, for example, a voltage lower than or equal to a threshold value is applied to the second gate electrode 22, and the potential of the second gate electrode 22 is lower than or equal to a second threshold value. Accordingly, an inversion layer is formed in the first region 36p. For example, holes flow from the second electrode 12 to the first semiconductor region 31 via the fourth semiconductor region 34, the first region 36p, and the fifth semiconductor region 35. As described above, a state in which the carrier injection efficiency is high is attained with the ON state of the second gate electrode 22.

Further, for example, the second gate electrode 22 is in the OFF state. That is, this is a state in which, for example, a voltage higher than the threshold value is applied to the second gate electrode 22, and the potential of the second gate electrode 22 is higher than the second threshold value. Accordingly, the inversion layer in the first region 36p disappears. For example, holes do not flow from the fourth semiconductor region 34 to the fifth semiconductor region 35. Injection of holes via the fifth semiconductor region 35 is prevented. Holes flow from the second electrode 12 to the first semiconductor region 31 via the fourth semiconductor region 34. As described above, a state in which the carrier injection efficiency is low is attained with the OFF state of the second gate electrode 22.

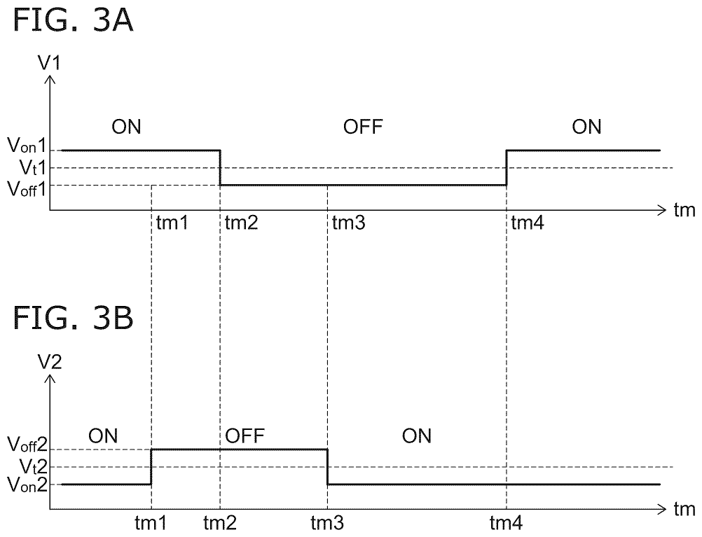

FIGS. 3A and 3B are schematic diagrams illustrating an operation of the semiconductor device according to the embodiment.

In FIGS. 3A and 3B, the horizontal axis represents time tm. FIG. 3A illustrates a voltage V1 of the first gate electrode 21. FIG. 3B illustrates a voltage V2 of the second gate electrode 22. For example, before time tm1, the voltage V1 is higher than or equal to a threshold voltage Vₜ1, and the first gate electrode 21 is in the ON state. For example, before time tm1, the voltage V1 is at a voltage Vₒₙ1 higher than the threshold voltage Vₜ1. The voltage Vₒₙ1 is positive with reference to the potential of the first electrode 11. Before time tm1, the voltage V2 is lower than or equal to a threshold voltage Vₜ2, and the second gate electrode 22 is in the ON state. For example, the voltage V2 is at a voltage Vₒₙ2 lower than the threshold voltage Vₜ2. The voltage Vₒₙ2 is negative with reference to the potential of the first electrode 11. Before time tm1, for example, the second gate electrode 22 is in the ON state, the injection efficiency of carriers from the back surface is high, and the hole concentration in the first semiconductor region 31 is high.

At time tm1, the voltage V2 becomes higher than the threshold voltage Vₜ2, and the second gate electrode 22 transitions to the OFF state. For example, at time tm1, the voltage V2 changes from the voltage Vₒₙ2 to a voltage V_{off}2. The voltage V_{off}2 is positive with reference to the potential of the first electrode 11. When the second gate electrode 22 transitions to the OFF state, the injection efficiency of carriers from the back surface decreases. At time tm2 after time tm1, the voltage V1 becomes lower than the threshold voltage Vₜ1, and the first gate electrode 21 transitions to the OFF state. For example, at time tm2, the voltage 1 changes from the voltage Vₒₙ1 to a voltage V_{off}1. The voltage V_{off}1 is negative with reference to the potential of the first electrode 11.

As described above, when the first gate electrode 21 is in the ON state, the second gate electrode 22 transitions from the ON state to the OFF state, and when the second gate electrode 22 is in the OFF state, the first gate electrode 21 transitions from the ON state to the OFF state. Since the second gate electrode 22 transitions to the OFF state before turning off in which the first gate electrode 21 transitions to the OFF state, for example, the carrier concentration in the first semiconductor region 31 is controlled and the turn-off time can be shortened. For example, the turn-off loss can be reduced. As an example, the length between time tm1 and time tm2 can be 0.1 microseconds or more and 100 microseconds or less.

At time tm3 after time tm2, the voltage V2 becomes lower than or equal to the threshold voltage Vₜ2, and the second gate electrode 22 transitions to the ON state. For example, at time tm3, the voltage V2 changes from the voltage V_{off}2 to the voltage Vₒₙ2. At time tm4 after time tm3, the voltage V1 becomes higher than or equal to the threshold voltage Vₜ1, and the first gate electrode 21 transitions to the ON state. For example, at time tm4, the voltage V1 changes from the voltage V_{off}1 to the voltage Vₒₙ1. Accordingly, the injection efficiency of carriers from the back surface increases, and the hole concentration increases.

As described above, when the first gate electrode 21 is in the OFF state, the second gate electrode 22 transitions from the OFF state to the ON state, and when the second gate electrode 22 is in the ON state, the first gate electrode 21 transitions from the OFF state to the ON state. Since the second gate electrode 22 is in the ON state, for example, the carrier concentration in the first semiconductor region 31 is controlled, and the ON voltage when the first gate electrode 21 transitions to the ON state can be reduced.

For example, the voltages of the first gate electrode 21 and the second gate electrode 22 are controlled by a control unit 70 (control circuit) schematically shown in FIG. 1. The control unit 70 controls the voltage V1 to switch the first gate electrode 21 between the ON state and the OFF state. The control unit 70 controls the voltage V2 to switch the second gate electrode 22 between the ON state and the OFF state. The semiconductor device 101 may include the control unit 70.

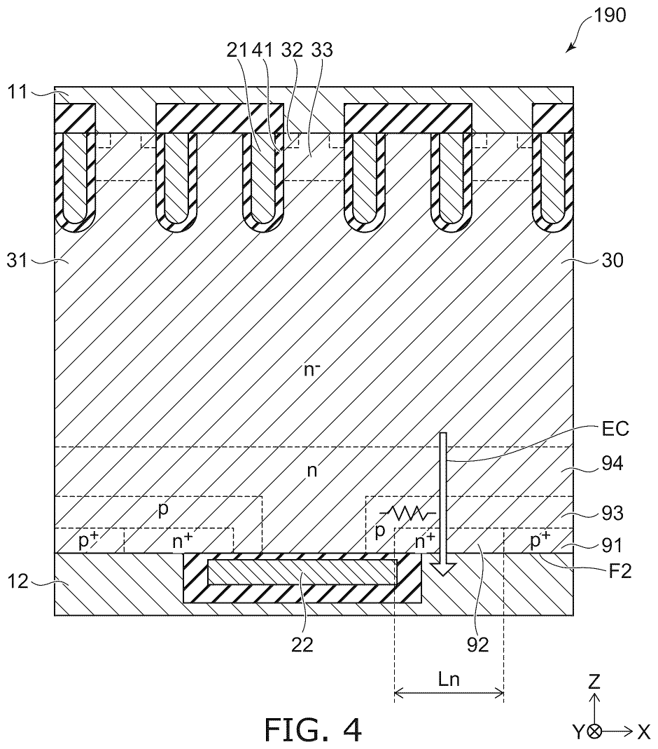

FIG. 4 is a schematic cross-sectional view of a semiconductor device according to a reference example.

In a semiconductor device 190 shown in FIG. 4, a p-channel MOSFET is not provided but an n-channel MOSFET is provided on the back surface side of the semiconductor layer 30. That is, the semiconductor layer 30 includes a p⁺-type region 91, an n⁺-type region 92, a p-type region 93, and an n-type region 94. The p⁺-type region 91 and the n⁺-type region 92 are provided on the second surface F2 and are in contact with the second electrode 12. The p-type region 93 is provided between the n-type region 94 and the n⁺-type region 92 and between the n-type region 94 and the p⁺-type region 91. A part of each of the n⁺-type region 92, the p-type region 93, and the n-type region 94 is opposed to the second gate electrode 22 with the second insulating region 42 interposed therebetween.

The n⁺-type region 92, the p-type region 93, the n-type region 94, the second insulating region 42, and the second gate electrode 22 function as an n-channel MOSFET. When the voltage of the second gate electrode 22 is controlled, ON/OFF of the n-channel MOSFET can be controlled. For example, when a positive voltage is applied to the second electrode 12 relative to the first electrode 11, the first gate electrode 21 is in the ON state, and the second gate electrode 22 is in the OFF state, electrons are injected from the front surface side, and holes are injected from the p⁺-type region 91 and the p-type region 93. Here, when the second gate electrode 22 transitions from the OFF state to the ON state, an inversion layer is formed in the p-type region 93, and electrons are discharged from the n-type region 94 to the second electrode 12 via the p-type region 93 and the n⁺-type region 92. Therefore, injection of holes from the p⁺-type region 91 and the p-type region 93 is prevented. As described above, the hole injection efficiency can be controlled by the second gate electrode 22.

Here, a parasitic element may be formed in the semiconductor device in which the n⁺-type region 92 is provided on the second surface F2. For example, in FIG. 4, the n⁺-type region 92, the p-type region 93, and the n-type region 94 arranged in the Z-direction form a parasitic element (n-p-n bipolar transistor). When the parasitic element is turned on, an electron current EC flows from the n-type region 94 to the n⁺-type region 92, and the hole injection efficiency decreases. For example, when the length Ln of the n⁺-type region 92 in the X-direction increases, a path through which electrons flow through the p-type region 93 on top of the n⁺-type region 92 becomes longer, and the resistance component due to the p-type region 93 increases. Therefore, the potential of the p-type region 93 increases, and this may allow the parasitic element to easily operate. In contrast, in the semiconductor device 101 according to the embodiment, the n-channel MOSFET need not be formed on the back surface side. According to the embodiment, the operation of the parasitic element can be prevented.

As described above, the sixth semiconductor region 36 includes the first region 36p and the second region 36q. For example, the threshold voltage of the p-channel MOSFET on the back surface side can be adjusted with the impurity concentration of the sixth semiconductor region 36.

The concentration of the second-conductivity-type impurity in the fifth semiconductor region 35 needs to be higher than the concentration of the second-conductivity-type impurity in the fourth semiconductor region 34. Since the concentration of the second-conductivity-type impurity in the fifth semiconductor region 35 is high, for example, in the ON state of the second gate electrode 22, the injection efficiency of holes via the fifth semiconductor region 35 can be increased. Since the concentration of the second-conductivity-type impurity in the fourth semiconductor region 34 is low, for example, in the OFF state of the second gate electrode 22, the injection efficiency of holes via the fourth semiconductor region 34 can be decreased. A change in the hole injection efficiency by the second gate electrode 22 can be increased.

The concentration of the second-conductivity-type impurity in the fifth semiconductor region 35 is, for example, 5×10¹⁷ atoms/cm³ or more 1×10¹⁹ atoms/cm³ or less. The concentration of the second-conductivity-type impurity in the fourth semiconductor region 34 is, for example, 5×10¹⁶ atoms/cm³ or more and 5×10¹⁷ atoms/cm³ or less. The concentration of the second-conductivity-type impurity in the fifth semiconductor region 35 is, for example, two times or more and 100 times or less the concentration of the second-conductivity-type impurity in the fourth semiconductor region 34.

As shown in FIG. 1, the sixth semiconductor region 36 includes a plurality of first regions 36p. The plurality of first regions 36p are arranged side by side in the X-direction. The plurality of fourth semiconductor regions 34 are arranged side by side in the X-direction. The plurality of fifth semiconductor regions 35 are arranged side by side in the X-direction. Each first region 36p is located between the fourth semiconductor region 34 and the fifth semiconductor region 35. That is, one first region 36p is provided between one fourth semiconductor region 34 and one fifth semiconductor region 35.

More specifically, as shown in FIG. 1, two first regions 36p (a region 36pa and a region 36pb) are provided between two fourth semiconductor regions 34 (between a region 34a and a region 34b). One fifth semiconductor region (a region 35a) is provided between two first regions 36p (between the region 36pa and the region 36pb). The region 34a and the region 34b are two fourth semiconductor regions 34 adjacent to each other in the X-direction among the plurality of fourth semiconductor regions 34. The region 36pa and the region 36pb are two first regions 36p adjacent to each other in the X-direction among the plurality of first regions 36p.

In this example, the two first regions 36p and the one fifth semiconductor region 35 are opposed to one second gate electrode 22 in the Z-direction. Accordingly, the current in the two first regions 36p can be controlled by the one second gate electrode 22.

More specifically, as shown in FIG. 1, the direction from a part (a first gate portion 22p) of the second gate electrode 22 toward the region 36pa is along the Z-direction. The direction from a part (a second gate portion 22q) of the second gate electrode 22 toward the region 36pb is along the Z-direction. The direction from a part (a third gate portion 22r) of the second gate electrode 22 toward the region 35a is along the Z-direction. The third gate portion 22r is between the first gate portion 22p and the second gate portion 22q, and the first gate portion 22p, the second gate portion 22q, and the third gate portion 22r are arranged side by side in the X-direction.

Two first regions 36p (the region 36pa and a region 36pc) are provided between two fifth semiconductor regions 35 (between the region 35a and a region 35b). One fourth semiconductor region 34 (the region 34a) is provided between the two first regions 36p (between the region 36pa and the region 36pc). The region 35a and the region 35b are two fifth semiconductor regions 35 adjacent to each other in the X-direction among the plurality of fifth semiconductor regions 35. The region 36pa and the region 36pc are two first regions 36p adjacent to each other in the X-direction among the plurality of first regions 36p.

The plurality of second insulating regions 42 are arranged side by side in the X-direction so as to correspond to the plurality of first regions 36p. The second insulating regions 42 are in contact with the first regions 36p respectively.

Between two second gate electrodes 22 (an electrode 22a and an electrode 22b) adjacent to each other in the X-direction among the plurality of second gate electrodes 22, the second electrode 12 need not be in contact with a semiconductor region of the first conductivity type. Accordingly, the parasitic element described in relation to the semiconductor device 190 of the reference example is not formed. The semiconductor layer 30 need not include a region of the first conductivity type that is in contact with the second electrode 12.

More specifically, as shown in FIG. 1, one fourth semiconductor region 34 (region 34a) is in contact with each of two second insulating regions 42 (an insulating region 42a and an insulating region 42b). The insulating region 42a and the insulating region 42b are two second insulating regions 42 adjacent to each other in the X-direction among the plurality of second insulating regions 42. The insulating region 42a is located between the region 36pa and the electrode 22a, and is in contact with the region 36pa. The insulating region 42b is located between the region 36pc and the electrode 22b, and is in contact with the region 36pc. Between the position of the insulating region 42a in the X-direction and the position of the insulating region 42b in the X-direction, a semiconductor region of the first conductivity type need not be provided on the second surface F2 of the semiconductor layer 30.

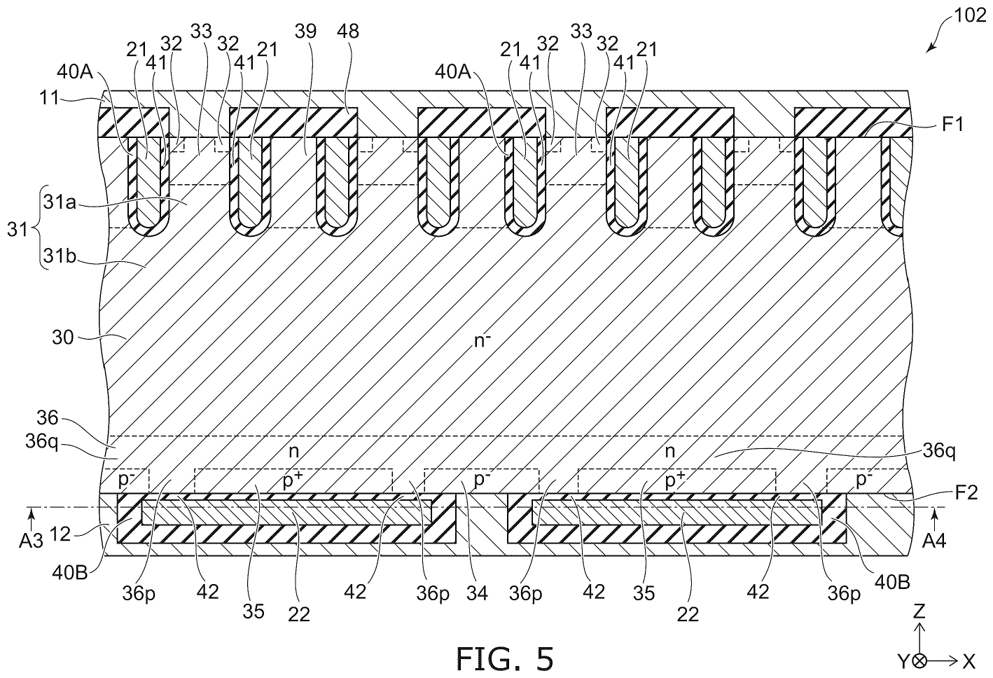

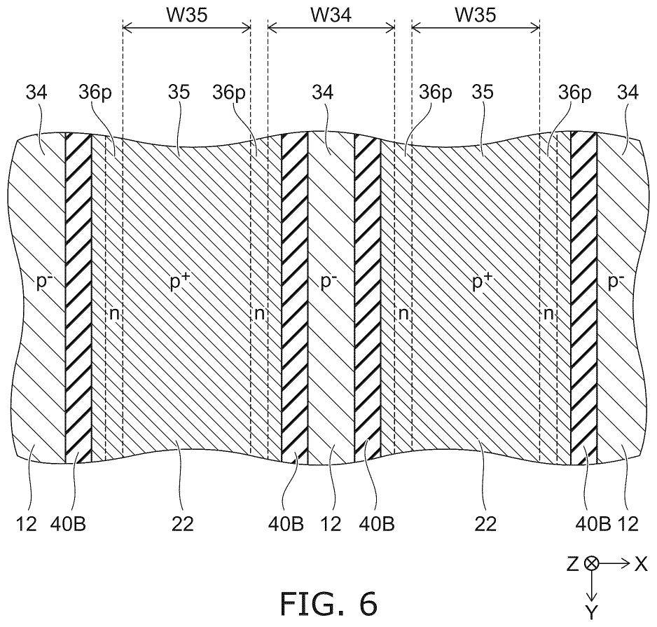

FIG. 5 and FIG. 6 are schematic cross-sectional views of a semiconductor device according to the embodiment.

FIG. 6 illustrates a cross section taken along line A3-A4 in FIG. 5. In FIG. 6, the positions of semiconductor regions on the back surface side of the semiconductor layer 30 are indicated by dashed lines. Further, the impurity concentrations (for example, n, p⁺, and p⁻) of these semiconductor regions are indicated.

A semiconductor device 102 shown in FIG. 5 and FIG. 6 is different from the semiconductor device 101 illustrated in FIG. 1 and so on in the magnitude relationship between the width of the fourth semiconductor region 34 and the width of the fifth semiconductor region 35. For the rest, the semiconductor device 102 needs to be similar to the semiconductor device 101.

As shown in FIG. 6, in the semiconductor device 102, a length W35 of the fifth semiconductor region 35 along the X-direction is longer than a length W34 of the fourth semiconductor region 34 along the X-direction.

Since the length W35 of the fifth semiconductor region 35 is long, for example, the injection efficiency of holes via the fifth semiconductor region 35 can be increased in the ON state of the second gate electrode 22. Since the length W34 of the fourth semiconductor region 34 is short, for example, the injection efficiency of holes via the fourth semiconductor region 34 can be decreased in the OFF state of the second gate electrode 22. A change in the hole injection efficiency by the second gate electrode 22 can be increased.

As in the semiconductor device 101 shown in FIG. 2, the length W34 of the fourth semiconductor region 34 may be longer than the length W35 of the fifth semiconductor region 35. When the length W34 of the fourth semiconductor region 34 is long, for example, the semiconductor layer 30 and the second electrode 12 are in contact with each other in a wide area, and a better contact is easily attained.

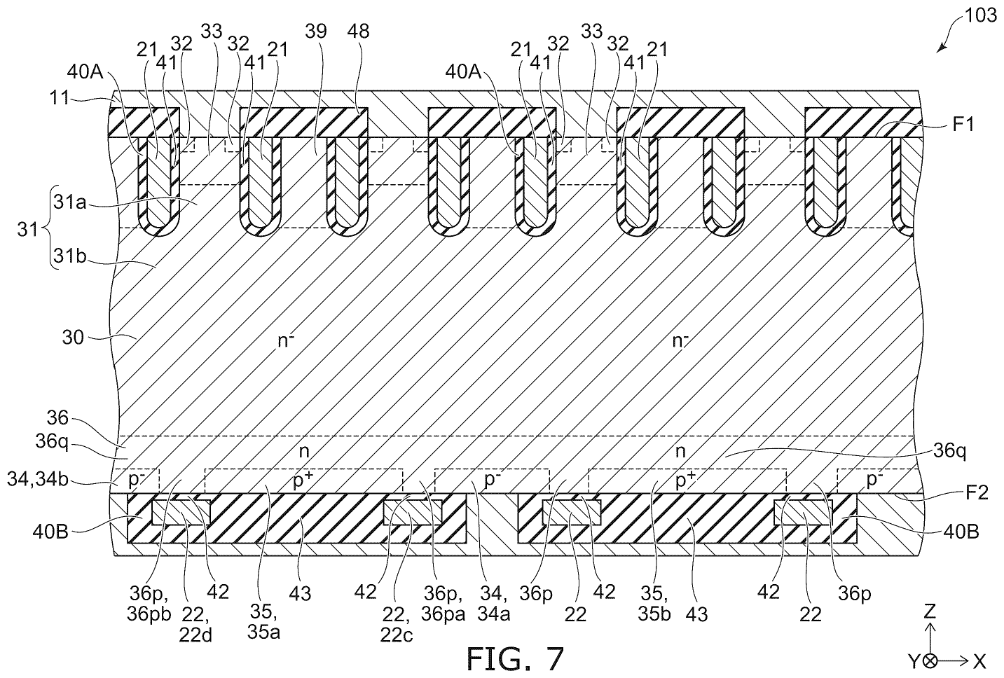

FIG. 7 is a schematic cross-sectional view of a semiconductor device according to the embodiment.

A semiconductor device 103 shown in FIG. 7 is different from the semiconductor device 101 or the semiconductor device 102 illustrated in FIG. 1 and so on in the disposition of the second gate electrode 22 and the second insulating portion 40B. For the rest, the semiconductor device 103 needs to be similar to the semiconductor device 101 or the semiconductor device 102.

The plurality of second gate electrodes 22 are provided side by side in the X-direction. Two second gate electrodes 22 (an electrode 22c and an electrode 22d) adjacent to each other in the X-direction among the plurality of second gate electrodes 22 are opposed to two first regions 36p (the region 36pa and the region 36pb) respectively in the Z-direction. That is, the direction from the electrode 22c toward the region 36pa is along the Z-direction. The direction from the electrode 22d toward the region 36pb is along the Z-direction.

The two second gate electrodes 22 (the electrode 22c and the electrode 22d) are covered with one second insulating portion 40B. The second insulating portion 40B includes a third insulating region 43 provided between the two second gate electrodes 22. One fifth semiconductor region 35 is opposed to the third insulating region 43 in the Z-direction. That is, for example, the direction from the third insulating region 43 between the electrode 22c and the electrode 22d toward the region 35a is along the Z-direction. Accordingly, for example, the gate capacitance of the second gate electrode 22 can be reduced. For example, loss in gate driving can be reduced.

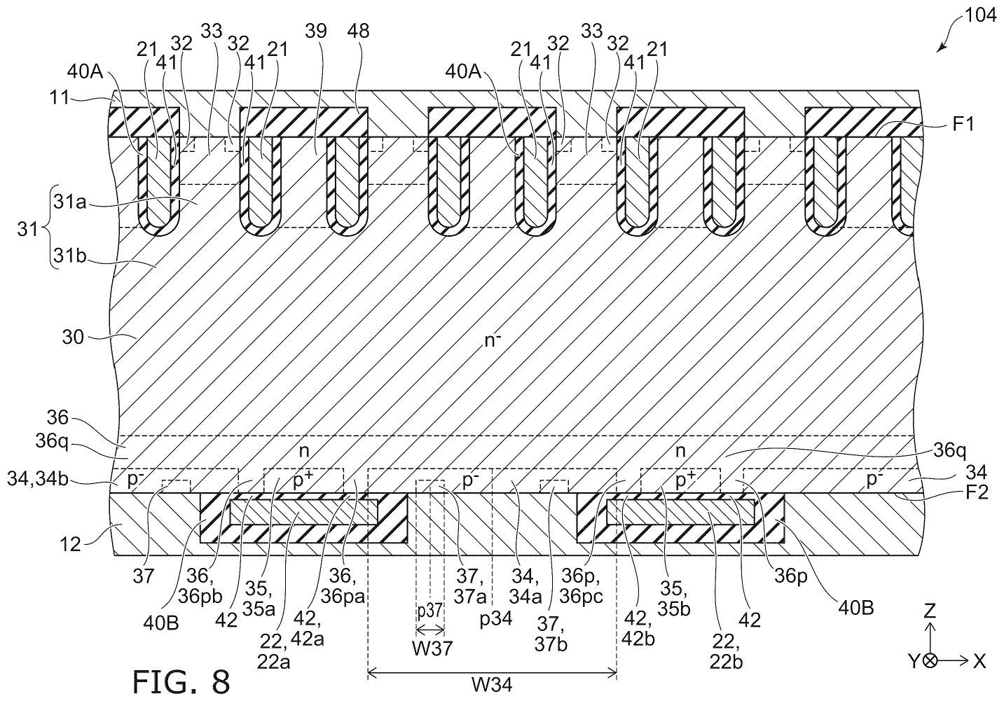

FIG. 8 is a schematic cross-sectional view of a semiconductor device according to the embodiment.

A semiconductor device 104 shown in FIG. 8 is different from the semiconductor device 101 shown in FIG. 1 and so on in that the semiconductor layer 30 includes a plurality of seventh semiconductor regions 37 (contact regions). For the rest, the semiconductor device 104 needs to be similar to the semiconductor device 101.

The seventh semiconductor region 37 is continuous with the fourth semiconductor region 34. The seventh semiconductor region 37 is of the second conductivity type. The concentration of the second-conductivity-type impurity in the seventh semiconductor region 37 is higher than the concentration of the second-conductivity-type impurity in the fourth semiconductor region 34. The seventh semiconductor region 37 is in contact with the second electrode 12 and is electrically connected to the second electrode 12. When the seventh semiconductor region 37 is provided, for example, the electric resistance between the semiconductor layer 30 and the second electrode 12 can be reduced.

In the example in FIG. 8, the seventh semiconductor region 37 (a region 37a) is located between the fourth semiconductor region 34 (the region 34a) and the second electrode 12. For example, a position p37 of the center of the seventh semiconductor region 37 in the X-direction is between a position p34 of the center of the fourth semiconductor region 34 in the X-direction and the position of the second gate electrode 22 (the second gate electrode 22 closest to the seventh semiconductor region 37) in the X-direction. The position of the region 37a in the X-direction is between the position of the center of the region 34a in the X-direction and the position of the electrode 22a in the X-direction.

As described above, the seventh semiconductor region 37 is disposed closer to the second gate electrode 22 than to the center of the fourth semiconductor region 34. Accordingly, for example, the distance between the fifth semiconductor region 35 and the seventh semiconductor region 37 can be shortened. For example, the resistance to the current flowing between the fifth semiconductor region 35 and the second electrode 12 via the seventh semiconductor region 37 can be reduced.

In the example in FIG. 8, the semiconductor layer 30 includes two seventh semiconductor regions 37 (the region 37a and a region 37b), which are in contact with one fourth semiconductor region 34 (the region 34a). The position p34 of the center of the fourth semiconductor region 34 in the X-direction is between the positions of the two seventh semiconductor regions 37 in the X-direction (between the position of the region 37a in the X-direction and the position of the region 37b in the X-direction).

The concentration of the second-conductivity-type impurity in the seventh semiconductor region 37 is, for example, 5×10¹⁷ atoms/cm³ or more and 5×10¹⁹ atoms/cm³ or less. In one example, among the semiconductor regions of the second conductivity type that are in contact with the second electrode 12, a region in which the concentration of the second-conductivity-type impurity is 5×10¹⁷ atoms/cm³ or more is the seventh semiconductor region 37 (in other words, a region in which the concentration of the second-conductivity-type impurity is less than 5×10¹⁷ atoms/cm³ is the fourth semiconductor region 34). For example, an area of the seventh semiconductor region 37, the area being in contact with the second electrode 12, is smaller than an area of the fourth semiconductor region 34, the area being in contact with the second electrode 12. For example, a length W37 of the seventh semiconductor region 37 along the X-direction is shorter than the length W34 of the fourth semiconductor region 34 along the X-direction. Since the seventh semiconductor region 37 having a higher impurity concentration than in the fourth semiconductor region 34 is narrow as described above, the injection efficiency of holes via the fourth semiconductor region 34 and the seventh semiconductor region 37 can be decreased.

When a semiconductor region having a high impurity concentration is in contact with the second insulating region 42, a change in a characteristic, such as the defect density of the second insulating region 42, may occur. For example, in the manufacturing process, enhanced diffusion of impurities may occur in the second insulating region 42. For this, the seventh semiconductor region 37 may be separated from the second insulating region 42 (the second insulating portion 40B). Accordingly, the influence of the semiconductor region having a high impurity concentration on the second insulating region 42 can be reduced.

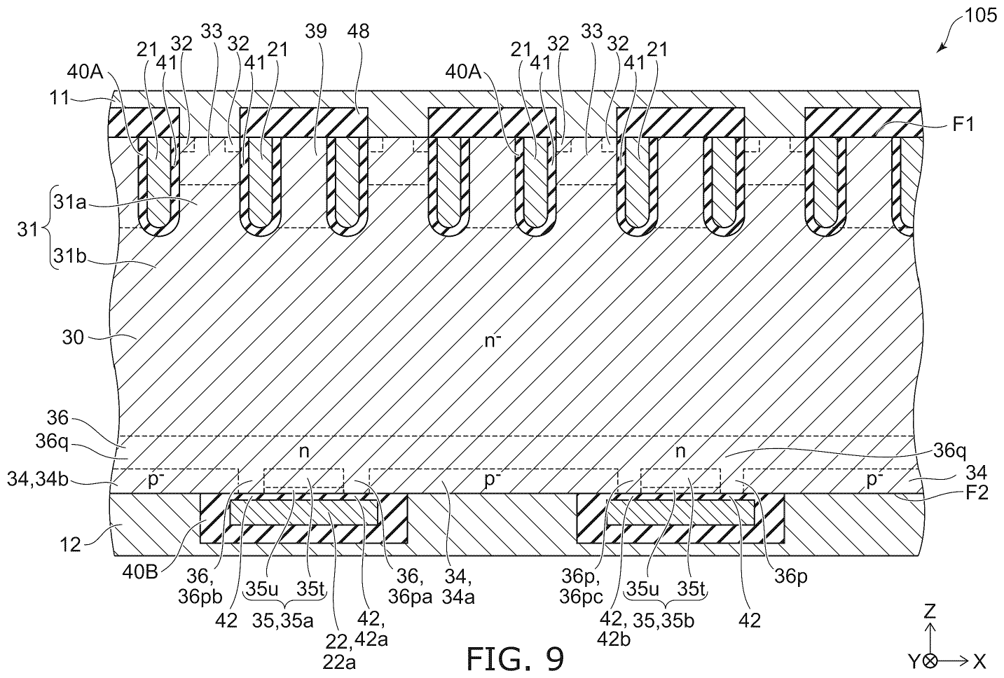

FIG. 9 is a schematic cross-sectional view of a semiconductor device according to the embodiment.

A semiconductor device 105 shown in FIG. 9 is different from the semiconductor device 101 illustrated in FIG. 1 and so on in that the fifth semiconductor region 35 includes a first partial region 35t and a second partial region 35u. For the rest, the semiconductor device 105 needs to be similar to the semiconductor device 101.

The second insulating region 42 is located between the second partial region 35u and the second gate electrode 22. The second insulating region 42 is in contact with the second partial region 35u. The first partial region 35t needs to be separated from the second insulating region 42.

In the example in FIG. 9, the second gate electrode 22, the second insulating region 42, the second partial region 35u, and the first partial region 35t overlap in the Z-direction. That is, the direction from the second gate electrode 22 toward the first partial region 35t is along the Z-direction. The direction from the second gate electrode 22 toward the second partial region 35u is along the Z-direction. The second partial region 35u is located between the first partial region 35t and the second gate electrode 22.

The first partial region 35t and the second partial region 35u are of the second conductivity type. The concentration of the second-conductivity-type impurity in the first partial region 35t is higher than the concentration of the second-conductivity-type impurity in the second partial region 35u. The concentration of the second-conductivity-type impurity in the first partial region 35t may be higher than the concentration of the second-conductivity-type impurity in the fourth semiconductor region 34. The concentration of the second-conductivity-type impurity in the second partial region 35u may be higher or lower than the concentration of the second-conductivity-type impurity in the fourth semiconductor region 34.

As described above, when the second partial region 35u having a lower impurity concentration than in the first partial region 35t is provided, the influence of the semiconductor region having a high impurity concentration on the second insulating region 42 can be reduced.

The concentration of the second-conductivity-type impurity in the first partial region 35t is, for example, 5×10¹⁷ atoms/cm³ or more and 1×10¹⁹ atoms/cm³ or less. The concentration of the second-conductivity-type impurity in the second partial region 35u is, for example, 5×10¹⁶ atoms/cm³ or more and 5×10¹⁷ atoms/cm³ or less.

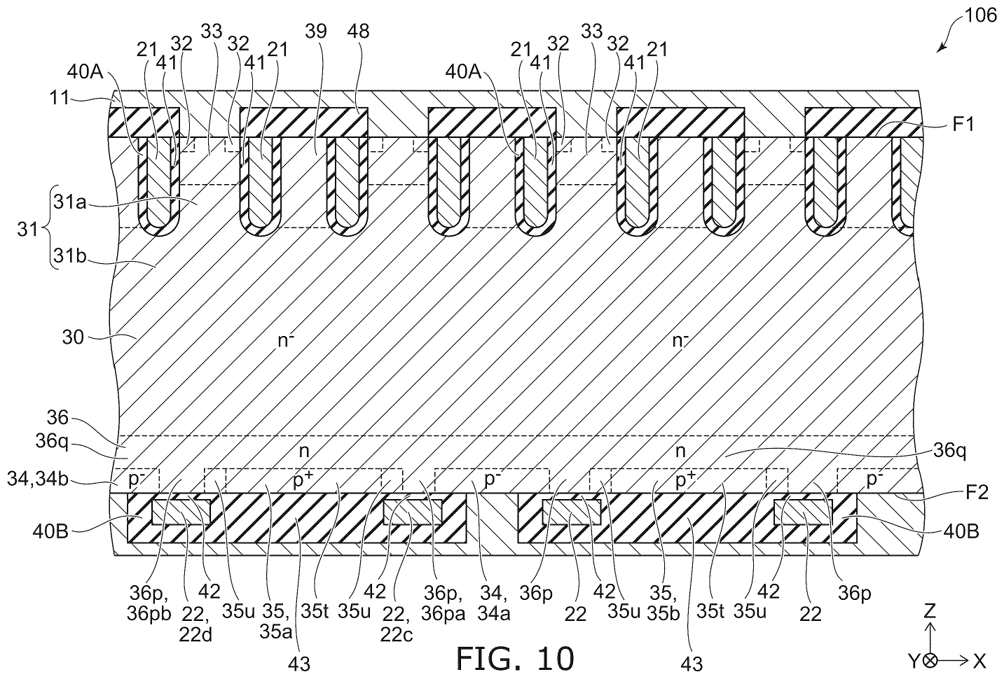

FIG. 10 is a schematic cross-sectional view of a semiconductor device according to the embodiment.

A semiconductor device 106 shown in FIG. 10 is different from the semiconductor device 103 shown in FIG. 7 in that the fifth semiconductor region 35 includes the first partial region 35t and the second partial region 35u. For the rest, the semiconductor device 106 needs to be similar to the semiconductor device 103.

Also in the example in FIG. 10, the second insulating region 42 is located between the second partial region 35u and the second gate electrode 22. The second insulating region 42 is in contact with the second partial region 35u. The concentration of the second-conductivity-type impurity in the first partial region 35t is higher than the concentration of the second-conductivity-type impurity in the second partial region 35u.

In the example in FIG. 10, one fifth semiconductor region 35 includes two second partial regions 35u and one first partial region 35t. The two second partial regions 35u are located at both end portions of the fifth semiconductor region 35 in the X-direction. The first partial region 35t is located between the two second partial regions 35u. That is, the direction from the first partial region 35t toward the second partial region 35u is along the X-direction.

The direction from the third insulating region 43 toward the first partial region 35t is along the Z-direction. The direction from the second gate electrode 22 toward the second partial region 35u is along the Z-direction.

Also in the semiconductor device 106, when the second partial region 35u having a relatively low impurity concentration is provided, the influence of the semiconductor region having a high impurity concentration on the second insulating region 42 can be reduced.

The embodiments may include the following configurations (for example, technical ideas).

### Configuration 1

A semiconductor device including:
a first electrode;
a second electrode, a direction from the second electrode toward the first electrode being along a first direction;
a semiconductor layer provided between the first electrode and the second electrode and having a first surface facing the first electrode and a second surface opposite to the first surface, the first surface and the second surface extending along a second direction perpendicular to the first direction;
a first gate electrode provided on a side of the semiconductor layer facing the first electrode;
a second gate electrode provided on a side of the semiconductor layer facing the second electrode, the second surface being located between the first surface and the second electrode;
a first insulating region provided between the first gate electrode and the semiconductor layer; and
a second insulating region provided between the second gate electrode and the second surface of the semiconductor layer,
the semiconductor layer including
   a first semiconductor region of a first conductivity type,
      a second semiconductor region of the first conductivity type, the second semiconductor region being provided between the first semiconductor region and the first electrode and being electrically connected to the first electrode,
      a third semiconductor region of a second conductivity type, the third semiconductor region being electrically connected to the first electrode, a part of the third semiconductor region being provided between the first semiconductor region and the second semiconductor region, being in contact with the first insulating region, and being opposed to the first gate electrode,
      a fourth semiconductor region of the second conductivity type, the fourth semiconductor region being provided between the first semiconductor region and the second electrode and being electrically connected to the second electrode,
      a fifth semiconductor region of the second conductivity type, the fifth semiconductor region being separated from the fourth semiconductor region in the second direction, and
      a sixth semiconductor region of the first conductivity type, the sixth semiconductor region including a first region, the first region being provided between the fourth semiconductor region and the fifth semiconductor region, being in contact with the second insulating region, and being opposed to the second gate electrode.

### Configuration 2

The semiconductor device according to configuration 1, in which
the sixth semiconductor region includes a second region provided between the first semiconductor region and the fifth semiconductor region, and
a concentration of a first-conductivity-type impurity in the sixth semiconductor region is higher than a concentration of a first-conductivity-type impurity in the first semiconductor region.

### Configuration 3

A semiconductor device including:
a first electrode;
a second electrode, a direction from the second electrode toward the first electrode being along a first direction;
a semiconductor layer provided between the first electrode and the second electrode;
a first gate electrode provided on a side of the semiconductor layer facing the first electrode;
a second gate electrode provided on a side of the semiconductor layer facing the second electrode;
a first insulating region provided between the first gate electrode and the semiconductor layer; and
a second insulating region provided between the second gate electrode and the semiconductor layer,
the semiconductor layer including
   a first semiconductor region of a first conductivity type,
      a second semiconductor region of the first conductivity type, the second semiconductor region being provided between the first semiconductor region and the first electrode and being electrically connected to the first electrode,
      a third semiconductor region of a second conductivity type, the third semiconductor region being electrically connected to the first electrode, a part of the third semiconductor region being provided between the first semiconductor region and the second semiconductor region, being in contact with the first insulating region, and being opposed to the first gate electrode,
      a fourth semiconductor region of the second conductivity type, the fourth semiconductor region being provided between the first semiconductor region and the second electrode and being electrically connected to the second electrode,
      a fifth semiconductor region of the second conductivity type, the fifth semiconductor region being separated from the fourth semiconductor region, and
      a sixth semiconductor region of the first conductivity type, the sixth semiconductor region including a first region and a second region, the first region being provided between the fourth semiconductor region and the fifth semiconductor region, being in contact with the second insulating region, and being opposed to the second gate electrode, the second region being provided between the first semiconductor region and the fifth semiconductor region, a concentration of a first-conductivity-type impurity in the sixth semiconductor region being higher than a concentration of a first-conductivity-type impurity in the first semiconductor region.

### Configuration 4

The semiconductor device according to any one of configurations 1 to 3, in which
a concentration of a second-conductivity-type impurity in the fifth semiconductor region is higher than a concentration of a second-conductivity-type impurity in the fourth semiconductor region.

### Configuration 5

The semiconductor device according to any one of configurations 1 to 4, in which
a length of the fifth semiconductor region along the second direction perpendicular to the first direction is shorter than a length of the fourth semiconductor region along the second direction.

### Configuration 6

The semiconductor device according to any one of configurations 1 to 4, in which
a length of the fifth semiconductor region along the second direction perpendicular to the first direction is longer than a length of the fourth semiconductor region along the second direction.

### Configuration 7

The semiconductor device according to any one of configurations 1 to 6, in which
the fourth semiconductor region includes a plurality of fourth semiconductor regions provided side by side in the second direction perpendicular to the first direction,
the first region includes a plurality of first regions provided side by side in the second direction,
two first regions adjacent to each other in the second direction among the plurality of first regions are provided between two fourth semiconductor regions adjacent to each other in the second direction among the plurality of fourth semiconductor regions,
one fifth semiconductor region is provided between the two first regions, and
the two first regions and the one fifth semiconductor region are opposed to one second gate electrode in the first direction.

### Configuration 8

The semiconductor device according to any one of configurations 1 to 6, in which
the fourth semiconductor region includes a plurality of fourth semiconductor regions provided side by side in the second direction perpendicular to the first direction,
the first region includes a plurality of first regions provided side by side in the second direction,
the second gate electrode includes a plurality of second gate electrodes provided side by side in the second direction,
two first regions adjacent to each other in the second direction among the plurality of first regions are provided between two fourth semiconductor regions adjacent to each other in the second direction among the plurality of fourth semiconductor regions,
one fifth semiconductor region is provided between the two first regions,
the two first regions are respectively opposed in the first direction to two second gate electrodes adjacent to each other in the second direction among the plurality of second gate electrodes, and
the one fifth semiconductor region is opposed in the first direction to a third insulating region provided between the two second gate electrodes.

### Configuration 9

The semiconductor device according to any one of configurations 1 to 7, in which
the fifth semiconductor region includes a first partial region and a second partial region,
a concentration of a second-conductivity-type impurity in the first partial region is higher than a concentration of a second-conductivity-type impurity in the second partial region, and
the second insulating region is located between the second partial region and the second gate electrode and is in contact with the second partial region.

### Configuration 10

The semiconductor device according to configuration 9, in which
a direction from the second gate electrode toward the first partial region is along the first direction,
a direction from the second gate electrode toward the second partial region is along the first direction, and
the second partial region is located between the first partial region and the second gate electrode.

### Configuration 11

The semiconductor device according to configuration 8, in which
the fifth semiconductor region includes a first partial region and a second partial region,
a concentration of a second-conductivity-type impurity in the first partial region is higher than a concentration of a second-conductivity-type impurity in the second partial region,
a direction from the third insulating region toward the first partial region is along the first direction,
a direction from the first partial region toward the second partial region is along the second direction, and
the second partial region is in contact with the second insulating region.

### Configuration 12

The semiconductor device according to any one of configurations 1 to 11, in which
the semiconductor layer further includes a seventh semiconductor region of a second conductivity type, the seventh semiconductor region being continuous with the fourth semiconductor region and being in contact with the second electrode, and
a concentration of a second-conductivity-type impurity in the seventh semiconductor region is higher than a concentration of a second-conductivity-type impurity in the fourth semiconductor region.

### Configuration 13

The semiconductor device according to configuration 12, in which
the seventh semiconductor region is located between the fourth semiconductor region and the second electrode.

### Configuration 14

The semiconductor device according to configuration 12 or 13, in which
a center position of the seventh semiconductor region in the second direction perpendicular to the first direction is between a center position of the fourth semiconductor region in the second direction and a position of the second gate electrode in the second direction.

### Configuration 15

The semiconductor device according to any one of configurations 12 to 14, in which
the seventh semiconductor region is a region having a concentration of a second-conductivity-type impurity of 5×10¹⁷ atoms/cm³ or more, and
an area of the seventh semiconductor region, the area being in contact with the second electrode, is smaller than an area of the fourth semiconductor region, the area being in contact with the second electrode.

### Configuration 16

The semiconductor device according to any one of configurations 1 to 15, in which
the second gate electrode includes a plurality of second gate electrodes provided side by side in the second direction perpendicular to the first direction,
the first region includes a plurality of first regions provided side by side in the second direction,
the second insulating region includes a plurality of second insulating regions provided side by side in the second direction,
the fifth semiconductor region includes a plurality of fifth semiconductor regions provided side by side in the second direction, and is in contact with the second insulating region,
the fourth semiconductor region includes a plurality of fourth semiconductor regions provided side by side in the second direction and is in contact with the second insulating region, and
the fifth semiconductor region is located between two first regions among the plurality of first regions, the two first regions being in contact with a same second insulating region among the plurality of second insulating regions.

### Configuration 17

The semiconductor device according to any one of configurations 1 to 16, in which
the second gate electrode includes a plurality of second gate electrodes provided side by side in the second direction perpendicular to the first direction,
the first region includes a plurality of first regions provided side by side in the second direction,
the second insulating region includes a plurality of second insulating regions provided side by side in the second direction,
the fifth semiconductor region includes a plurality of fifth semiconductor regions provided side by side in the second direction,
two first regions adjacent to each other in the second direction among the plurality of first regions are provided between two fifth semiconductor regions adjacent to each other in the second direction among the plurality of fifth semiconductor regions,
one fourth semiconductor region is provided between the two first regions,
the plurality of second insulating regions are in contact with the plurality of first regions respectively, and
one fourth semiconductor region is in contact with each of two second insulating regions adjacent to each other in the second direction among the plurality of second insulating regions.

### Configuration 18

The semiconductor device according to configuration 17, in which
the semiconductor layer further includes two seventh semiconductor regions of the second conductivity type, the two seventh semiconductor regions being continuous with the fourth semiconductor region and being in contact with the second electrode,
a concentration of a second-conductivity-type impurity in the seventh semiconductor regions is higher than a concentration of a second-conductivity-type impurity in the fourth semiconductor region,
the two seventh semiconductor regions are between one fourth semiconductor region and the second electrode, and
a center position of the fourth semiconductor region in the second direction is between positions of the two seventh semiconductor regions in the second direction.

### Configuration 19

The semiconductor device according to any one of configurations 1 to 18, in which
when the first gate electrode is in an ON state, the second gate electrode transitions from an ON state to an OFF state, and
when the second gate electrode is in the OFF state, the first gate electrode transitions from the ON state to an OFF state.

### Configuration 20

The semiconductor device according to any one of configurations 1 to 19, in which
when the first gate electrode is in an OFF state, the second gate electrode transitions from an OFF state to an ON state, and
when the second gate electrode is in the ON state, the first gate electrode transitions from the OFF state to an ON state.

In the embodiments, information about, for example, the shapes of the semiconductor regions is obtained by, for example, observation with an electron microscope. Information about the impurity concentrations in the semiconductor regions is obtained by, for example, EDX (Energy Dispersive X-ray Spectroscopy) or SIMS (Secondary Ion Mass Spectrometry). Information about the carrier concentrations in the semiconductor regions is obtained by, for example, SCM (Scanning Capacitance Microscopy).

According to the embodiments, a semiconductor device capable of reducing the ON voltage can be provided.

In the specification, a case of “being electrically connected” includes a case of “being connected by direct contact” and also includes a case of “being connected with, for example, another conductive member interposed”.

In the specification, “perpendicular” and “parallel” not only refer to strictly perpendicular and strictly parallel but also allow, for example, variations caused during, for example, the manufacturing process, and need to be substantially perpendicular and substantially parallel.

When one direction is along another direction, the one direction and the other direction may be parallel to each other.

Certain embodiments of the invention have been described above with reference to specific examples. However, the invention is not limited to these specific examples. For example, those skilled in the art may similarly practice the invention by selecting, as appropriate, specific configurations of components included in the semiconductor devices from known art. Such practice is included in the scope of the invention to the extent that similar effects are attained.

Any two or more components in the specific examples may be combined within the extent of technical feasibility and are included in the scope of the invention to the extent that the gist of the invention is included.

Moreover, all semiconductor devices practicable by design modification made as appropriate by those skilled in the art based on the semiconductor devices described above as embodiments of the invention are also within the scope of the invention to the extent that the gist of the invention is included.

Moreover, various variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor device comprising:
a first electrode;
a second electrode, a direction from the second electrode toward the first electrode being along a first direction;
a semiconductor layer provided between the first electrode and the second electrode and having a first surface facing the first electrode and a second surface opposite to the first surface, the first surface and the second surface extending along a second direction perpendicular to the first direction;
a first gate electrode provided on a side of the semiconductor layer facing the first electrode;
a second gate electrode provided on a side of the semiconductor layer facing the second electrode, the second surface being located between the first surface and the second electrode;
a first insulating region provided between the first gate electrode and the semiconductor layer; and
a second insulating region provided between the second gate electrode and the second surface of the semiconductor layer,
the semiconductor layer including
a first semiconductor region of a first conductivity type,
a second semiconductor region of the first conductivity type, the second semiconductor region being provided between the first semiconductor region and the first electrode and being electrically connected to the first electrode,
a third semiconductor region of a second conductivity type, the third semiconductor region being electrically connected to the first electrode, a part of the third semiconductor region being provided between the first semiconductor region and the second semiconductor region, being in contact with the first insulating region, and being opposed to the first gate electrode,
a fourth semiconductor region of the second conductivity type, the fourth semiconductor region being provided between the first semiconductor region and the second electrode and being electrically connected to the second electrode,
a fifth semiconductor region of the second conductivity type, the fifth semiconductor region being separated from the fourth semiconductor region in the second direction, and
a sixth semiconductor region of the first conductivity type, the sixth semiconductor region including a first region, the first region being provided between the fourth semiconductor region and the fifth semiconductor region, being in contact with the second insulating region, and being opposed to the second gate electrode.

2. The semiconductor device according to claim 1, wherein
the sixth semiconductor region includes a second region provided between the first semiconductor region and the fifth semiconductor region, and
a concentration of a first-conductivity-type impurity in the sixth semiconductor region is higher than a concentration of a first-conductivity-type impurity in the first semiconductor region.

3. A semiconductor device comprising:
a first electrode;
a second electrode, a direction from the second electrode toward the first electrode being along a first direction;
a semiconductor layer provided between the first electrode and the second electrode;
a first gate electrode provided on a side of the semiconductor layer facing the first electrode;
a second gate electrode provided on a side of the semiconductor layer facing the second electrode;
a first insulating region provided between the first gate electrode and the semiconductor layer; and
a second insulating region provided between the second gate electrode and the semiconductor layer,
the semiconductor layer including
a first semiconductor region of a first conductivity type,
a second semiconductor region of the first conductivity type, the second semiconductor region being provided between the first semiconductor region and the first electrode and being electrically connected to the first electrode,
a third semiconductor region of a second conductivity type, the third semiconductor region being electrically connected to the first electrode, a part of the third semiconductor region being provided between the first semiconductor region and the second semiconductor region, being in contact with the first insulating region, and being opposed to the first gate electrode,
a fourth semiconductor region of the second conductivity type, the fourth semiconductor region being provided between the first semiconductor region and the second electrode and being electrically connected to the second electrode,
a fifth semiconductor region of the second conductivity type, the fifth semiconductor region being separated from the fourth semiconductor region, and
a sixth semiconductor region of the first conductivity type, the sixth semiconductor region including a first region and a second region, the first region being provided between the fourth semiconductor region and the fifth semiconductor region, being in contact with the second insulating region, and being opposed to the second gate electrode, the second region being provided between the first semiconductor region and the fifth semiconductor region, a concentration of a first-conductivity-type impurity in the sixth semiconductor region being higher than a concentration of a first-conductivity-type impurity in the first semiconductor region.

4. The semiconductor device according to claim 1, wherein
a concentration of a second-conductivity-type impurity in the fifth semiconductor region is higher than a concentration of a second-conductivity-type impurity in the fourth semiconductor region.

5. The semiconductor device according to claim 1, wherein
a length of the fifth semiconductor region along the second direction perpendicular to the first direction is shorter than a length of the fourth semiconductor region along the second direction.

6. The semiconductor device according to claim 1, wherein
a length of the fifth semiconductor region along the second direction perpendicular to the first direction is longer than a length of the fourth semiconductor region along the second direction.

7. The semiconductor device according to claim 1, wherein
the fourth semiconductor region includes a plurality of fourth semiconductor regions provided side by side in the second direction perpendicular to the first direction,
the first region includes a plurality of first regions provided side by side in the second direction,
two first regions adjacent to each other in the second direction among the plurality of first regions are provided between two fourth semiconductor regions adjacent to each other in the second direction among the plurality of fourth semiconductor regions,
one fifth semiconductor region is provided between the two first regions, and
the two first regions and the one fifth semiconductor region are opposed to one second gate electrode in the first direction.

8. The semiconductor device according to claim 1, wherein
the fourth semiconductor region includes a plurality of fourth semiconductor regions provided side by side in the second direction perpendicular to the first direction,
the first region includes a plurality of first regions provided side by side in the second direction,
the second gate electrode includes a plurality of second gate electrodes provided side by side in the second direction,
two first regions adjacent to each other in the second direction among the plurality of first regions are provided between two fourth semiconductor regions adjacent to each other in the second direction among the plurality of fourth semiconductor regions,
one fifth semiconductor region is provided between the two first regions,
the two first regions are respectively opposed in the first direction to two second gate electrodes adjacent to each other in the second direction among the plurality of second gate electrodes, and
the one fifth semiconductor region is opposed in the first direction to a third insulating region provided between the two second gate electrodes.

9. The semiconductor device according to claim 1, wherein
the fifth semiconductor region includes a first partial region and a second partial region,
a concentration of a second-conductivity-type impurity in the first partial region is higher than a concentration of a second-conductivity-type impurity in the second partial region, and
the second insulating region is located between the second partial region and the second gate electrode and is in contact with the second partial region.

10. The semiconductor device according to claim 9, wherein
a direction from the second gate electrode toward the first partial region is along the first direction,
a direction from the second gate electrode toward the second partial region is along the first direction, and
the second partial region is located between the first partial region and the second gate electrode.

11. The semiconductor device according to claim 8, wherein
the fifth semiconductor region includes a first partial region and a second partial region,
a concentration of a second-conductivity-type impurity in the first partial region is higher than a concentration of a second-conductivity-type impurity in the second partial region,
a direction from the third insulating region toward the first partial region is along the first direction,
a direction from the first partial region toward the second partial region is along the second direction, and
the second partial region is in contact with the second insulating region.

12. The semiconductor device according to claim 1, wherein
the semiconductor layer further includes a seventh semiconductor region of a second conductivity type, the seventh semiconductor region being continuous with the fourth semiconductor region and being in contact with the second electrode, and
a concentration of a second-conductivity-type impurity in the seventh semiconductor region is higher than a concentration of a second-conductivity-type impurity in the fourth semiconductor region.

13. The semiconductor device according to claim 12, wherein
the seventh semiconductor region is located between the fourth semiconductor region and the second electrode.

14. The semiconductor device according to claim 12, wherein
a center position of the seventh semiconductor region in the second direction perpendicular to the first direction is between a center position of the fourth semiconductor region in the second direction and a position of the second gate electrode in the second direction.

15. The semiconductor device according to claim 12, wherein
the seventh semiconductor region is a region having a concentration of a second-conductivity-type impurity of 5×10¹⁷ atoms/cm³ or more, and
an area of the seventh semiconductor region, the area being in contact with the second electrode, is smaller than an area of the fourth semiconductor region, the area being in contact with the second electrode.

16. The semiconductor device according to claim 1, wherein
the second gate electrode includes a plurality of second gate electrodes provided side by side in the second direction perpendicular to the first direction,
the first region includes a plurality of first regions provided side by side in the second direction,
the second insulating region includes a plurality of second insulating regions provided side by side in the second direction,
the fifth semiconductor region includes a plurality of fifth semiconductor regions provided side by side in the second direction, and is in contact with the second insulating region,
the fourth semiconductor region includes a plurality of fourth semiconductor regions provided side by side in the second direction and is in contact with the second insulating region, and
the fifth semiconductor region is located between two first regions among the plurality of first regions, the two first regions being in contact with a same second insulating region among the plurality of second insulating regions.

17. The semiconductor device according to claim 1, wherein
the second gate electrode includes a plurality of second gate electrodes provided side by side in the second direction perpendicular to the first direction,
the first region includes a plurality of first regions provided side by side in the second direction,
the second insulating region includes a plurality of second insulating regions provided side by side in the second direction,
the fifth semiconductor region includes a plurality of fifth semiconductor regions provided side by side in the second direction,
two first regions adjacent to each other in the second direction among the plurality of first regions are provided between two fifth semiconductor regions adjacent to each other in the second direction among the plurality of fifth semiconductor regions,
one fourth semiconductor region is provided between the two first regions,
the plurality of second insulating regions are in contact with the plurality of first regions respectively, and
one fourth semiconductor region is in contact with each of two second insulating regions adjacent to each other in the second direction among the plurality of second insulating regions.

18. The semiconductor device according to claim 17, wherein
the semiconductor layer further includes two seventh semiconductor regions of the second conductivity type, the two seventh semiconductor regions being continuous with the fourth semiconductor region and being in contact with the second electrode,
a concentration of a second-conductivity-type impurity in the seventh semiconductor regions is higher than a concentration of a second-conductivity-type impurity in the fourth semiconductor region,
the two seventh semiconductor regions are between one fourth semiconductor region and the second electrode, and
a center position of the fourth semiconductor region in the second direction is between positions of the two seventh semiconductor regions in the second direction.

19. The semiconductor device according to claim 1, wherein
when the first gate electrode is in an ON state, the second gate electrode transitions from an ON state to an OFF state, and
when the second gate electrode is in the OFF state, the first gate electrode transitions from the ON state to an OFF state.

20. The semiconductor device according to claim 1, wherein
when the first gate electrode is in an OFF state, the second gate electrode transitions from an OFF state to an ON state, and
when the second gate electrode is in the ON state, the first gate electrode transitions from the OFF state to an ON state.
